(19) United States
(12) Patent Application Publication
(10) Pub. No.: US 2024/0070446 A1
(43) Pub. Date: Feb. 29, 2024

(54) NEUROMORPHIC COMPUTING

(71) Applicant: SECQAI LTD., London (GB)

(72) Inventor: Rahul Tyagi, London (GB)

(21) Appl. No.: 18/454,911

(22) Filed: Aug. 24, 2023

(30) Foreign Application Priority Data
Aug. 26, 2022 (GB) 2212441.6

(51) Int. Cl. G06N 3/063; G11C 11/16; G11C 11/54; H10B 51/20

(52) U.S. Cl. CPC G06N 3/063; G11C 11/161; G11C 11/54; H10B 51/20

(57) ABSTRACT

The invention relates to utilizing a magnetoresistance as part of a computing element in a computing device. In particular, the invention relates to neural networks and neuromorphic computing devices that implement magnetoresistance to adjust certain parameters of the neural network/neuromorphic computing devices. Such a computing device can comprise electronic circuitry comprising source circuitry and read-out circuitry, one or more magnetoresistive elements, and a control element, configured to magnetize each of the one or more magnetoresistive element to adjust the resistance of each magnetoresistive element between at least three resistance values. Such a computing device can be used to operate an artificial neural network.

### CROSS-REFERENCE TO RELATED APPLICATION

This application claims priority to Great Britain Application No. 2212441.6 filed on Aug. 26, 2022, the disclosure of which is incorporated herein by reference in its entirety.

### FIELD OF THE INVENTION

The present invention relates to utilizing a magnetoresistance as part of a computing element in a computing device. In particular, the present invention relates to neural networks and neuromorphic computing devices that implement magnetoresistance to adjust certain parameters of the neural network/neuromorphic computing devices.

### BACKGROUND

Neuromorphic computing is a field of computing that mimics the architecture of the brain to reduce the power consumption of artificial intelligence. Neuromorphic hardware can be used to implement an artificial neural network, which are computing systems having a collection of connected artificial neurons. The connections between the neurons, also referred to as synapses, transmit signals between the artificial neurons. The neural network also comprises a plurality of weights that be increased/decreased so as to adjust the strength of the signal at a connection/synapse.

Neuromorphic neural networks may further implement spiked neural networks, whereby neurons will only transmit a signal once the signal reaches a threshold. Such an action is similar to a neural action potential in the human brain.

One of the predominant requirements for neuromorphic computing is to take two inputs and multiply them together. Over time one of the inputs becomes defined and can be stored inside the computational unit. This definition occurs whilst the device is trained. Initially weights are randomly assigned to each computational unit and as the system learns, the weights are modified per epoch. This requires less energy to retrieve the memory from the data source as you now only rely on one direct input signal and one signal that is inherently retained within the compute unit. A secondary effect that may be observed is the time to run the neuromorphic computer compared to digital computation.

The fundamental calculation of all artificial intelligence (AI) is multiplication and can include vector and matrix multiplication. Multiplication in circuitry can be performed a number of ways, including taking advantage of the principles of Ohm's Law (which sets out that Voltage is equal to Current multiplied by Resistance). For example, with a fixed electric current, any adjustments to the resistance will ultimately impact the voltage across said resistance (such that the voltage is effectively the product of the resistance and the current).

Traditional multiplication in neuromorphic computing is performed with a potential barrier concept using electric fields. That is, multiplication can be performed by using electron accumulation in a material to induce a resistive effect on electrons passing through a circuit.

However, one drawback of relying on electric fields to induce a resistive effect is that the electric field needs to be maintained, which requires an active voltage supply and constant power delivery. Such a technique is therefore not ideal for long term storage of the resistance values, or low power calculations.

As further background, hard disk drives (otherwise known as hard disks, hard drives, or fixed disks) are known for storing memory using ferromagnetic elements. They work by spinning a disc rapidly and reading/writing information from circular rings on the disc. The memory is written through the use of ferromagnetism, whereby an electromagnet induces magnetism into a section of the disc. In other words, the hard disk drive is an electro-mechanical data storage device that stores/receives digital data using magnetic storage elements. As the material of the disc is ferromagnetic it retains its magnetism aligned to the electromagnet that produced it. As the disc rotates, data is written by the electromagnet based on its polarity and therefore the polarity induced into the disc, with a north upwards facing field defined as a one and a north downwards facing field as a 0. This memory is written traditionally as binary bits (as 1s and 0s).

### SUMMARY

There is provided, according to an embodiment of the present invention, a method for operating an artificial neural network arranged on a computing device. The computing device comprises: electronic circuitry comprising source circuitry and read-out circuitry; one or more magnetoresistive elements; and a control element, configured to magnetize each of the one or more magnetoresistive elements so as to adjust the resistance of each magnetoresistive element between at least three resistance values. The source circuitry is configured to apply a respective voltage or current to each of the one or more magnetoresistive elements, and the read-out circuitry is configured to output a respective voltage across each of the one or more magnetoresistive elements and/or a current through each of the one or more magnetoresistive elements. The method comprises, in a calculation phase: applying, via the source circuitry, a respective voltage or current to each of the one or more magnetoresistive elements, and outputting, via the read-out circuitry, a respective voltage across or a respective current through each of the one or more magnetoresistive elements. The adjustable resistance of each of the one or more magnetoresistive elements is associated with a respective weight of the artificial neural network.

By applying a certain current through an adjustable resistance, the voltage across the adjustable resistance can be detected. In this way, the voltage corresponds to the product of current and resistance, such that the configuration acts as an effective multiplier circuit.

In contrast, if a certain voltage is applied across the adjustable resistance, then a current through the adjustable resistance can be detected. In this way, monitoring the current corresponds to a quotient defined by the voltage divided by the resistance. In other words, in such a configuration, the configuration acts an effective divider circuit.

Magnetoresistance (or magnetoresistivity) refers to a property of a material, whereby the electrical resistance of the material changes in an externally-applied magnetic field. In other words, a magnetoresistive element is an element that exhibits magnetoresistance, and can be controlled via an externally-applied magnetic field to adjust the electrical resistance.

Some types of magnetoresistance include geometrical magnetoresistance, common positive magnetoresistance, negative magnetoresistance, anisotropic magnetoresistance, giant magnetoresistance (GMR), tunnel magnetoresistance (TMR), colossal magnetoresistance (CMR), and extraordinary magnetoresistance (EMR).

The control element refers to an element able to apply an external magnetization to the magnetoresistive element, and optionally includes one or more processors associated with one or more memory elements storing a set of instructions for operating the element (so as to magnetize each of the one or more magnetoresistive elements).

In some instances, the control element may comprise a read/write head of a hard disc drive and an associated processor that instructs and operates the read/write head.

By adjusting an external magnetic field, or magnetizing one of the one or more magnetoresistive elements to a certain degree, the resistance of said magnetoresistive element can be controlled (in response to one or more of the above magnetoresistive effects). It is to be understood that this resistance can be adjusted across a range between a minimum resistance value and a maximum resistance value, including one or more intermediate resistance values between the minimum and maximum value.

The control element may be configured to adjust the resistance of the one or more magnetoresistive elements to any number of discrete points between the minimum and maximum resistance values of the magnetoresistive elements. For example, the control element may be configured to set the resistance of a magnetoresistive element to 10 discrete points between a minimum and a maximum resistance values. There may be any number of configurable points between the minimum and maximum values (e.g. 2, 5, 20, 100, etc.). As the value of the resistance in each magnetoresistive element corresponds to a weight in an artificial neural network, the number of available intermediate points that can be determined will affect the ultimate resolution of the weight value.

In one example, the maximum resistance value of the magnetoresistive element may be the resistance value of the magnetoresistive element when no external magnetic field is applied. In other examples, the minimum resistance value of the magnetoresistive element may be the resistance of the magnetoresistive element when no external magnetic field is applied.

In some instances, the read-out circuitry may comprise hardware for measuring a voltage or current at the output of a magnetoresistive element. If this is the case, an output can be determined at the output of each magnetoresistive element, which may be beneficial for training of a neural network and/or performing multiplication and division with the magnetoresistive elements.

In other instances, the read-out circuitry may simply refer to the circuitry and/or wiring at the output of the magnetoresistive element, for transferring an output voltage and/or current signal from the magnetoresistive element to a subsequent component.

In some instances, the source circuitry may comprise hardware for generating a specific voltage or current to be applied to the magnetoresistive element. It may include current sources and voltage sources, each of which may be implemented with passive sources (e.g. a voltage source in combination with resistive elements), and active sources with and without feedback (e.g. a FET constant current source). Such a current or voltage source may be configurable so as take an input voltage or current and generate a second voltage or current based on the input voltage or current, to be applied to the magnetoresistive element.

In other instances, the source circuitry may simply refer to the circuitry and/or wiring at the input of the magnetoresistive element, for transferring an input voltage and/or current signal to the magnetoresistive element.

That is, the source circuitry may have its current or voltage level set by a preceding component (e.g. by directly connecting a preceding artificial neuron in an artificial neural network to the magnetoresistive element), or it may receive a signal from the preceding component (e.g. the preceding artificial neuron) and actively generate a new signal on the basis of the received signal to apply to the magnetoresistive element.

One benefit of this method is that magnetoresistive elements can be used to set weights of an artificial neural network. By controlling the resistance values with magnetic controls, as opposed to electric controls, significantly less power can be utilized during operation (as no power supply needs to be provided to sustain a certain voltage). Moreover, as the magnetoresistive elements respond to an external magnetic field, it is simpler to provide a computing device in which the weights can be set via magnetization, and the device can be stored without losing the values of the weights. Methods for storing charge with electric elements (e.g. capacitors) are subject to current-bleeding effects, which make them less desirable for long-term storage of data (e.g. the weight values set by the magnetoresistive elements).

In some embodiments, the method comprises, for each of the one or more magnetoresistive elements: receiving, from a respective input circuit, the voltage or current to be applied to the respective magnetoresistive element, and outputting the respective voltage across each of the one or more magnetoresistive elements and/or the current through each of the one or more magnetoresistive elements to a respective output circuit.

In other words, a respective portion of the source circuitry associated with a magnetoresistive element may receive a signal from the respective input circuit and generate a voltage or current signal in accordance with the signal from the input circuit (so that the signal passes through the magnetoresistive element). Similarly, the voltage or current output by the read-out circuitry can be passed to the respective output circuit.

It may be understood that each magnetoresistive element may be associated with an individual input circuit, or with a respective portion of a single input circuit associated with each and every magnetoresistive element.

Similarly, each magnetoresistive element may be associated with an individual output circuit, or with a respective portion of a single output circuit associated with each and every magnetoresistive element.

In some cases, each magnetoresistive element can be connected, at the same time, to respective input and output circuits. In this way, as all of the magnetoresistive elements are simultaneously connected to source circuitry and read-out circuitry, the computing device can perform parallel processing using each magnetoresistive element as a weight of the artificial neural network.

In some embodiments, the method further comprises: disconnecting at least one of the respective input circuits from the respective source circuitry, disconnecting at least one of the one or more magnetoresistive elements from the respective source circuitry, disconnecting at least one of the one or more magnetoresistive elements from the respective read-out circuitry, and/or disconnecting the read-out circuitry from at least one of the respective output circuits.

In some cases, it may be advantageous to disconnect either the input circuit of a magnetoresistive element from the source circuitry (i.e. from a respective portion of the source circuitry associated with the magnetoresistive element), or the output circuit of a magnetoresistive element from the read-out circuitry (i.e. from a respective portion of the read-out circuitry associated with the magnetoresistive element). Alternatively, or in addition, the magnetoresistive elements can be disconnected from the circuit, so as to prevent current flow through the magnetoresistive element entirely.

By doing this, the current flow through the magnetoresistive element can be prevented, therefore actively preventing the computing device from performing a calculation with a specific magnetoresistive element.

The disconnect function can be provided with a disconnect switch, which can be implemented with a relay, MOSFET, BJT, or any other suitable electronic switch.

In some embodiments, the input circuit is a first artificial neuron circuit, and wherein the output circuit is a second artificial neuron circuit.

In other embodiments, the input circuit can comprise one or more first artificial neuron circuits, and/or the output circuit can comprise one or more second artificial neuron circuits.

An artificial neuron is an elementary unit in an artificial neural network. It is configured to receive one or more inputs, and to perform a mathematical function on them (e.g. a summing function).

In some embodiments, the method further comprises, in a training phase, setting the resistance of each of the one or more magnetoresistive elements with the control element.

The training phase may refer to a time during which each of the weights of the artificial neural network are set, by adjusting each of the respective resistance values of the one or more magnetoresistive elements.

The training phase may further incorporate finding the appropriate weights of the network on the computing device, using, e.g. gradient backward propagation.

Alternatively, the weights may be determined external to the computing device (e.g. in a software simulation of the neural network) and simply applied to the respective magnetoresistive elements in the computing device during the training phase.

In some embodiments, each of the one or more magnetoresistive elements is a magnetic storage element.

By taking advantage of hardware already associated with magnetic storage elements, but implementing techniques for controlling the resistance of the storage element, a magnetoresistive element can be achieved, which can be used for performing multiplication and/or division.

In some embodiments, the magnetic storage element is a magnetic storage element of a ferromagnetic hard disc drive.

By utilizing magnetic storage elements of a ferromagnetic hard disc drive, the magnetic heads (read/write heads) present in the ferromagnetic hard disc drive can be used to magnetize each of the magnetic storage elements, drastically simplifying the process of “training” the artificial neural network.

In some instances, each magnetic storage element of the hard disc drive corresponds to a magnetic region of a platter (i.e. disc) surface on the disc drive (corresponding to a certain width in the radial direction of the platter [e.g. 200-300 nm wide] and extending a certain distance in the circumferential/down-track direction [e.g. 20-35 nm]).

In some embodiments, in the training phase, one or more discs of the ferromagnetic hard disc drive are rotating so as to allow the resistance of each of the one or more magnetoresistive elements to be set; and in the calculation phase, the one or more discs of the ferromagnetic hard disc drive are not rotating.

In order to write data to each of the magnetic storage elements of the hard disc drive (so as to set the resistance value/weight of the neural network), it is necessary to rotate the one or more discs of the hard disc drive, so that the disk read/write heads can contact the respective magnetic storage elements.

However, once the resistance values of each of the magnetoresistive elements have been set, there is no longer a need to spin the one or more discs to operate the computing device, which is advantageous because further power savings can be achieved.

The electrical connections between artificial neurons in a neural network (i.e. the artificial synapses) are fixed and do not rely upon a read/write head. That is, the computing device can operate entirely based on the pre-set configuration of connections and the trained weights of the neural network (the set resistances of each of the magnetoresistive elements).

There is also provided, according to an embodiment of the present invention, a computing device configured to perform multiplication or division. The computing device comprises: electronic circuitry comprising source circuitry and read-out circuitry; one or more magnetoresistive elements; and a control element, configured to magnetize each of the one or more magnetoresistive elements so as to adjust the resistance of each magnetoresistive element between at least three resistance values. The source circuitry is configured to apply a voltage or current to each of the one or more magnetoresistive elements, and the read-out circuitry is configured to output a respective voltage across each of the one or more magnetoresistive elements and/or a respective current through each of the one or more magnetoresistive elements.

By providing a computing device configured to perform multiplication or division with magnetoresistive elements, a low power computing device can be achieved.

In its most simple implementation, the computing device can be configured to perform a single multiplication or division function. However, a plurality of magnetoresistive elements can also be provided, which provides the capability of parallel processing.

In other implementations, each multiplication/division element (i.e. each magnetoresistive element with corresponding read-out and source circuitry) can be connected to one another in any number of configurations, including serially. That is, the output of one multiplication/division element can be connected to the input of a second multiplication/division element. This allows for two, distinct multiplicative factors to be applied to a single input.

In some embodiments of the computing device, for each of the one or more magnetoresistive elements the source circuitry is configured to receive the voltage or current to be applied to the respective magnetoresistive element from a respective input circuit, and the read-out circuitry is configured to output the respective voltage across each of the one or more magnetoresistive elements and/or the current through each of the one or more magnetoresistive elements from each magnetoresistive element to a respective output circuit.

In some embodiments of the computing device, each of the one or more magnetoresistive elements is a magnetic storage element.

In some embodiments, each magnetic storage element is a magnetic storage element of a ferromagnetic hard disc drive.

There is additionally provided, according to an embodiment of the present invention, an artificial synapse circuit in an artificial neural network, the artificial synapse circuit comprising electronic circuitry comprising source circuitry and read-out circuitry; an magnetoresistive element; and a control element, configured to magnetize the magnetoresistive element so as to adjust the resistance of the magnetoresistive element between at least three resistance values. The source circuitry is configured to apply a voltage or current to the magnetoresistive element, the read-out circuitry is configured to output a respective voltage across each of the magnetoresistive element and/or a respective current through the magnetoresistive element, and the adjustable resistance of each of the one or more magnetoresistive elements is associated with a weight of the artificial synapse in the artificial neural network. The source circuitry is configured to receive the voltage or current to be applied to the magnetoresistive element from a first artificial neuron circuit, and the read-out circuitry is configured to output the respective voltage across the magnetoresistive element and/or the respective current through the magnetoresistive element to a second artificial neuron circuit.

It is understood that an artificial synapse refers to a connection between neurons, that has a weight value associated with it. It may alternatively be considered that the artificial synapse performs the function of a dendrite in a biological neuron (the multiplication effect) as well as function of a biological synapse (passing the signal between neurons).

Each artificial synapse may have a direction associated with it. That is, the artificial synapse may be configured to take an input signal from a first artificial neuron, apply a multiplication factor to it (i.e. apply a weight), and output the multiplied signals to a second artificial neuron. This direction may be unidirectional (feedforward) or it may be bidirectional (and also incorporate a feedback mechanism).

In some embodiments of the artificial synapse circuit, the artificial synapse circuit further comprises a synapse disconnect switch, the synapse disconnect switch configured to disconnect the first artificial neuron circuit from the source circuitry, the source circuitry from the magnetoresistive element, the magnetoresistive element from the read-out circuitry, and/or disconnect the read-out circuitry from the second artificial neuron circuit.

For the avoidance of doubt, where a disconnect switch is present within an artificial neuron circuit of the artificial neural network, it may be referred to as a neural disconnect switch. Similarly, where a disconnect switch is present within an artificial synapse circuit of the artificial neural network, it may be referred to as a synapse disconnect switch. Of course, the disconnect switches can be arranged in different locations of the circuitry so as to provide the same effect of preventing current flow.

Artificial neural networks are provided with a plurality of layers, where each layer comprises a number of artificial neurons.

There may be an input layer, an output layer, and optionally, one or more hidden layers, recurrent layers, kernel layers, and/or convolution layers, etc. in the artificial neural network.

The layers, and the respective nodes (i.e. artificial neurons) within the layers can be connected to one another by artificial synapses in a number of different topologies. The topologies may include any of the following: perceptron, feed forward, radial basis network, deep feed forward, recurrent neural network, long/short term memory, gated recurrent unit, auto encoder, variational AE, denoising AE, sparse AE, deep convolutional network, deconvolutional network, deep convolutional inverse graphics network, generative adversarial network, liquid state machine, extreme learning machine, echo state network, deep residual network, Kohonen network, support vector machine, and neural Turing machine. These topologies define the connections of the nodes between respective layers.

For example, in one embodiment, the artificial neural network can comprise a feed forward neural network topology. In such a topology, all nodes are fully connected and the activation signal flows from an input layer to output (in a feedforward manner), with a single hidden layer between input and output layers.

With this in mind, a disconnect function can be provided with a disconnect switch within at least one synapse or neuron (but preferably in each synapse and/or each neuron), which can be implemented with a relay, MOSFET, BJT, or any other suitable electronic switch.

That is, with a disconnect switch, the current flow through the magnetoresistive element can be prevented, therefore actively disconnecting the artificial synapse circuit from the artificial neural network.

This is beneficial because it allows the connections between artificial neurons to be controlled more effectively than merely adjusting the weights of a magnetoresistance element. In other words, an artificial network can be provided initially with a topology where each node in a first layer is connected to each node in a second layer, and so on. By turning off individual connections in the artificial synapses via respective disconnect switches, the topology of the artificial neural network can be controlled.

Moreover, where a calculated weight associated with the artificial synapse is effectively zero, it may be more effective to disconnect the synapse rather than set an appropriate magnetoresistance value close to zero.

In some embodiments, the source circuitry is configured to receive the voltage or current to be applied from the first artificial neuron circuit and from one or more additional neuron circuits.

In other words, an artificial synapse circuit can be configured to receive signals from a plurality of artificial neuron circuits, instead of just from one artificial neuron circuit. In some instances, the plurality of artificial neuron circuits may be connected to the artificial synapse circuit via disconnect switches (e.g. one or more logic gates), and there may be a control unit configured to control the disconnect switches and connect selectively the one or more artificial neuron circuits to the artificial synapse circuit.

It may be understood that a control unit refers to circuitry configured to operate an artificial neural network, including adjusting topologies of the neural network via disconnect switches and/or adjusting the timing control of signal propagation through the layers of the artificial neural network.

There may be a single control unit connected to each of the synapses and neurons of the ANN, or there may alternatively be a plurality of single control units so as to provide a distributed control approach (whereby each synapse and/or neuron is associated with a respective control unit)

The control unit may be implemented with a processor associated with the control element, or it may be implemented with one or more entirely separate processors. The one or more separate processors may present within circuitry connected to the artificial synapse circuitry.

The benefit of this level of controllability is that the selection of which neurons are incident on a respective synapse provides a much greater level of configurability with regard to neural connectivity, which allows for post-manufacture adjustment of the neural network topology.

In some embodiments of the artificial synapse circuit, the artificial neural network is a spiking neural network, and wherein the artificial synapse circuit further comprises: a voltage gate, wherein the voltage gate is configured to allow current to flow to an output of the artificial synapse circuit if the voltage across the magnetoresistive element exceeds a threshold voltage of the voltage gate.

A spiking neural network refers to an artificial neural network that more closely mimics natural neural networks, because the electrical signals transferred between neurons are transmitted only under certain circumstances (i.e. an activation signal is output once a threshold is reached). This is a parallel to natural neural networks, in which information is transmitted when a membrane potential of the neuron is met.

As a result, in an artificial spiking neural network, information can be encoded within the path route that the neuron firing takes and by the time at which neurons fire.

Such networks are beneficial for a number of reasons. First, information can be transmitted using very weak signals as the rate encoding is very robust to noise. Second, they bring new learning algorithms for unsupervised learning. Indeed, spiking neurons allow the implementation of bio-inspired local learning rules such as Hebbian learning and Spike-Time-Dependant-Plasticity (STDP). These learning rules resume to enhancing a weight of a synapse if the activities of the two neurons that it connects seem to be correlated and decreasing it otherwise. It thus allows the network to learn in real time and by itself. Finally, thanks to the spatio-temporal information encoding that they use, spiking neural networks open possibilities to exploit the network dynamics for learning. For example synchronization of spike trains allows to decode the network outputs from synchronization patterns. Such dynamical phenomena are present in brain and allow it to compute with a smaller number of neurons. First demonstrations of efficient learning using synchronization have been demonstrated in neuromorphic computing with spintronic neurons, thus proving the interest of dynamical neuron models for artificial neural networks.

In some embodiments of the artificial synapse circuit, the threshold voltage of the voltage gate is variable.

In some embodiments of the artificial synapse circuit, wherein the voltage gate comprises a magnetoresistive circuit that allows the threshold voltage to be varied. For example, the voltage gate can be implemented with a magnetic tunnel junction (MTJ) style system (where a magnetic tunnel junction comprises a component consisting of two ferromagnets separated by a thin insulator).

There is further provided, according to an embodiment of the present invention, an artificial neural network circuit, comprising: a plurality of artificial neuron circuits; and a plurality of artificial synapse circuits according to an embodiment to the present invention. Each of the plurality of artificial synapse circuits is connected between a respective two of the plurality of artificial neuron circuits, and the resistance of the magnetoresistive element in each artificial synapse circuit corresponds to a weight in the artificial neural network.

In some embodiments of the artificial neural network circuit, the voltage gate of each synapse circuit allows current to flow from one of its respective artificial neuron circuits to the other of its respective artificial neuron circuits.

In some embodiments of the artificial neural network circuit, each magnetoresistive element is a magnetic storage element and each of the artificial synapse circuits is connected between its respective two artificial neuron circuits by conductive traces.

In some embodiments, each magnetic storage element is a magnetic storage element of a ferromagnetic hard disc drive.

In some embodiments of the artificial neural network circuit, each of the plurality of artificial neuron circuits is configured to receive signals from one or more of the artificial synapse circuits, sum and/or compute a weighted average of said signals, and output the sum and/or weighted average.

In some embodiments of the method, the computing device, the artificial synapse circuit, or the artificial spiked neural network circuit, each magnetoresistive element comprises a layered structure, the layered structure comprising a first magnetic material, a non-magnetic material, and a second magnetic material.

In some embodiments of the method, the computing device, the artificial synapse circuit, or the artificial spiked neural network circuit, the control element is configured to magnetize the first magnetic material and the second material of each magnetoresistive element into a parallel and into an anti-parallel arrangement so as to adjust the resistance.

By controlling the magnetization of adjacent ferromagnetic layers in this way, the resistance of each magnetoresistive element can be controlled via the giant magnetoresistance (GMR) effect. This effect is a quantum mechanical effect that arises in multilayers of alternating ferromagnetic and non-magnetic conductive layers. Such an effect is beneficial because there is a significant change in the electrical resistance based on whether the layers are magnetized into a parallel or an anti-parallel arrangements, which allows for a wider range of control for the multiplication factor.

In some embodiments of the method, the computing device, the artificial synapse circuit, or the artificial spiked neural network circuit, the magnetoresistive element is a single layer of material.

By controlling an external magnetic field through a single layer of material, other magnetoresistive effects can be used to control the resistance values, including, e.g. colossal magnetoresistance.

### BRIEF DESCRIPTION OF THE DRAWINGS

FIG. 1 illustrates an exemplary artificial neural network, having an input layer, a single hidden layer, and an output layer.

FIG. 2 illustrates a schematic of an artificial neural network according to an embodiment of the present invention.

FIG. 3 illustrates a multilayer arrangement of ferromagnetic and non-magnetic layers.

FIG. 4 illustrates the giant magnetoresistive effect (GMR) that arises with control of the arrangement of FIG. 3.

FIG. 5 illustrates alternative arrangements of the ferromagnetic and non-magnetic layers.

FIG. 6 illustrates an exemplary magnetic storage element in a hard disc drive.

FIG. 7 illustrates a schematic of another artificial neural network according to an embodiment of the invention, with further detail provided regarding one of the artificial neurons and one of the artificial synapses.

FIG. 8 illustrates a schematic of another artificial neural network according to an embodiment of the invention.

FIG. 9 illustrates an arrangement in which a magnetoresistive element of an artificial synapse circuit can be configured to receive signals from one or more artificial neuron circuits.

FIG. 10 illustrates an arrangement for monitoring whether an artificial neuron circuit has fired.

FIG. 11 illustrates a schematic of a non-spiking artificial neural network, according to an embodiment of the invention.

FIG. 12 illustrates a top-down view of an arrangement of magnetoresistive elements on a hard disc drive.

FIG. 13 illustrates a computing device according to the present invention, where multiple hard disc drives are connected to one another to form the computing device.

### DETAILED DESCRIPTION

Artificial neural networks (ANNs), usually simply called neural networks (NNs) are computing systems inspired by the biological neural networks that constitute animal brains.

An ANN is based on a collection of connected units or nodes called artificial neurons, which loosely model the neurons in a biological brain. Each connection, like the synapses in a biological brain, can transmit a signal to other neurons.

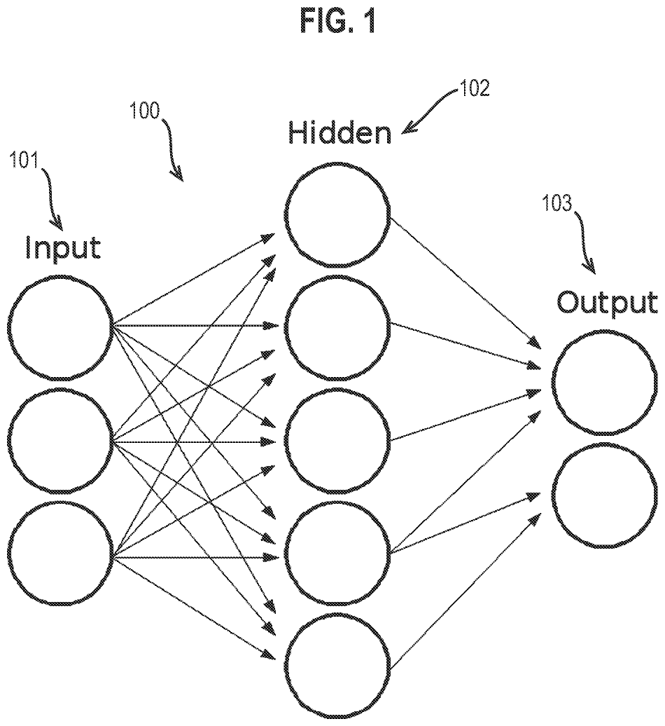

As shown in FIG. 1, an artificial neural network 100 may comprise a number of neurons, each arranged into one of a plurality of layers 101, 102, 103. In FIG. 1, there is provided a single input layer 101, a single output layer 103, and a hidden layer 102 between the input and output layers.

Other layers and number of layers are also known in neural networks, as are the specific connections between the nodes in the respective layers.

For example, an exemplary ANN according to the present invention may comprise an input layer, an output layer, and optionally, one or more hidden layers, recurrent layers, kernel layers, and/or convolution layers.

The layers, and the respective nodes (i.e. artificial neurons) within the layers can be connected to one another by artificial synapses in a number of different topologies. In an embodiment of the present invention, the ANN may comprise any one of the following topologies: feed forward, radial basis network, deep feed forward, recurrent neural network, long/short term memory, gated recurrent unit, auto encoder, variational AE, denoising AE, sparse AE, deep convolutional network, deconvolutional network, deep convolutional inverse graphics network, generative adversarial network, liquid state machine, extreme learning machine, echo state network, deep residual network, Kohonen network, support vector machine, and neural Turing machine. These topologies define the connections of the nodes between respective layers.

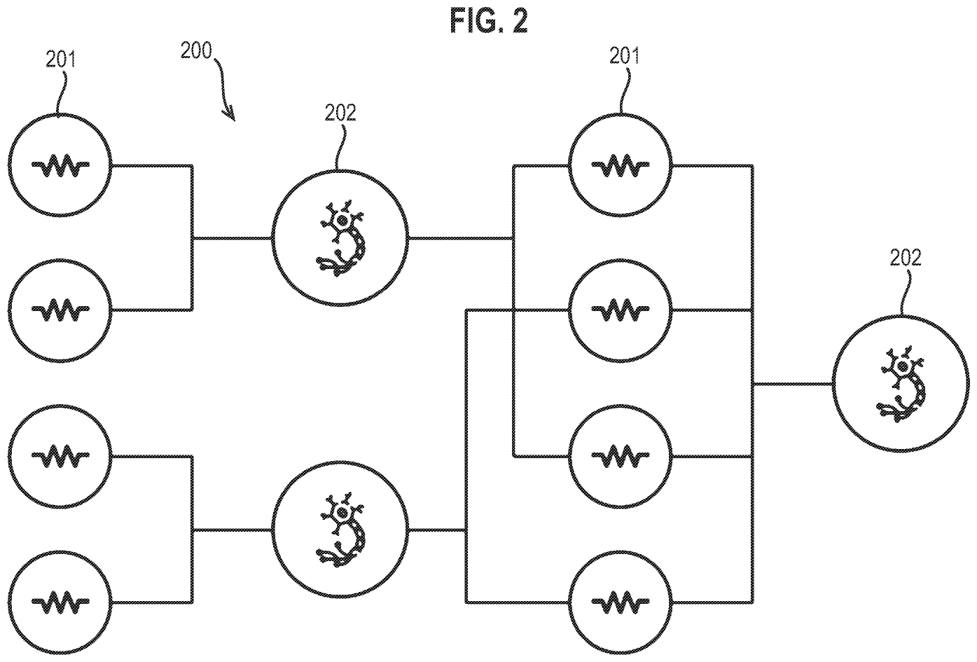

As shown in FIG. 2, an ANN 200 according to the present invention may comprise a number of resistive elements 201, which act to provide the weighting/multiplication function of the artificial neural network 200.

It may be understood that these resistive elements 201 are incorporated within the artificial synapses of the ANN 200. That is, each resistive element shown in FIG. 2 acts as a single, or set of, synapse connections between one neuron and a second neuron.

According to the present invention, the resistive element 200 is provided with a magnetoresistive element, which can be considered any element that changes the value of its electrical resistance in response to an externally-applied magnetic field.

In some embodiments, the material of the magnetoresistive element comprises a hard magnetic material (i.e. a permanent magnet, or a magnetic material that retains its magnetism), so as to allow the resistive effects to be retained. In other words, the magnetoresistive element may be configured to be magnetized such that the magnetization is retained without any further external field being applied.

The “hard” magnetic material may comprise a ferromagnetic material, such as iron, nickel, cobalt, the alloys of iron, nickel, and cobalt, and the alloys of rare-earth metals.

As shown in FIG. 2, there is a layer in the ANN 200 having two neurons 202. Each of these neurons 202 is configured to receive electrical signals from two respective synapses, and each of these synapses is configured to apply a weight (i.e. multiplication factor) to its respective electrical signal.

Such a weight is applied by virtue of Ohm's Law (V=I*R). That is, by controlling, via a control element, the resistance value through each magnetoresistive element, a different multiplication factor can be applied to a fixed current value.

Each neuron 202 is then configured to sum its input signals and pass the output onto respective synapse circuits (in this case, each neuron outputs to two distinct synapse circuits).

The magnetoresistive element can take a number of forms and take advantage of any number of magnetoresistive effects. Known magnetoresistive effects which can be implemented in the present invention include geometrical magnetoresistance, common positive magnetoresistance, negative magnetoresistance, anisotropic magnetoresistance, giant magnetoresistance (GMR), tunnel magnetoresistance (TMR), colossal magnetoresistance (CMR), and extraordinary magnetoresistance (EMR).

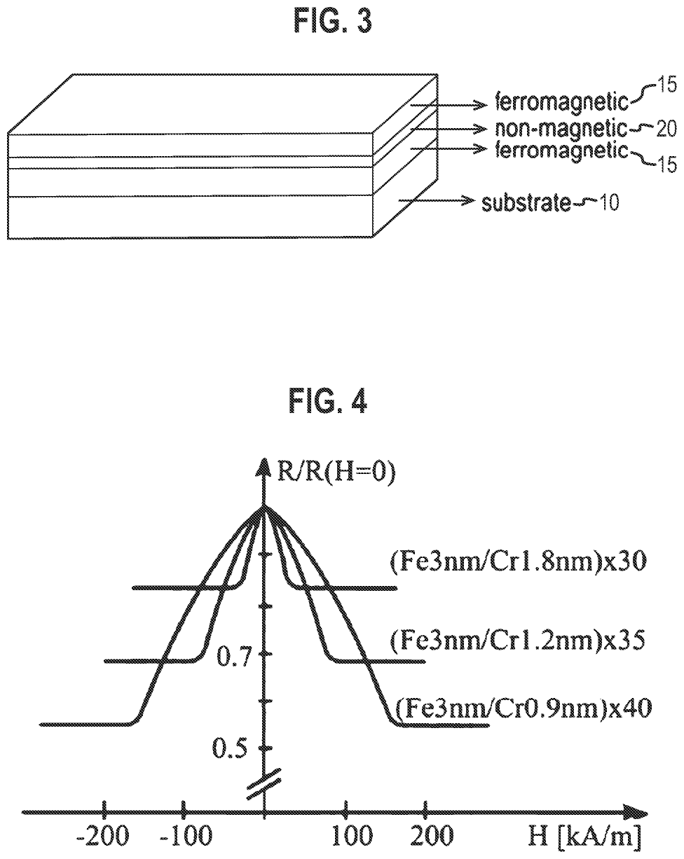

FIG. 3 illustrates an arrangement of materials in an exemplary magnetoresistive element. In this case, there is an alternating stack of ferromagnetic material 15 and non-magnetic material 20, positioned on a substrate 10.

Whilst this figure depicts a single sandwich of ferromagnetic material 15 and non-magnetic material 20, it is understood that any number of layers may be provided (e.g. ferromagnetic-non-magnetic-ferromagnetic-non-magnetic-ferromagnetic), so long as the layers are alternating in the same pattern.

The arrangement of layers in this way allows for a giant magnetoresistive effect to arise when adjacent ferromagnetic layers are magnetically polarised in a certain way, and an external field is applied to the structure.

As shown in FIG. 4, for a given sandwich type multilayer with magnetizations aligned initially antiparallel (i.e. external magnetic field of H=0) can exhibit a large resistance drop (e.g. more than 50% as compared to the maximum resistance) after application of an external magnetic field.

FIG. 4 depicts an exemplary effect of GMR given a certain Fe/Cr superlattice, given different thicknesses of the Cr spacer.

The GMR effect is a quantum mechanical effect observed in such a thin film structure comprising ferromagnetic layers separated by non-magnetic layers. The effect arises due to the spin of electrons in each of the materials (which may have two directions, up and down). When the spin across the material has been magnetized, one type of spin (e.g. up spin) may experience a resistance that is different than that that of the other type of spin (e.g. down spin).

In context of the artificial neural network, when each of the magnetoresistive elements comprises such a sandwich structure, the resistance may be at the highest level prior to training (maximum resistance), and once training commences the resistance across synapses may decrease (via application of a magnetic field of a certain strength) to identify the optimal trained position (adjusted resistance).

To further explain this GMR phenomenon, the following will occur when adjacent layers of ferromagnetic material are magnetized with the same polarity (i.e. both layers magnetized with fields in the same direction). Strong scattering occurs for electrons with spin antiparallel to the direction of magnetization, while weak scattering occurs for electrons with spin parallel to the direction of magnetization. In the state where two adjacent ferromagnetic layers are magnetized with the same polarity, electrons with up spin are weakly scattered both in the first and second ferromagnetic layer, whereas the down spin electrons are strongly scattered in both ferromagnetic layers. Since the up and down spin channels are connected in parallel, the total resistance of the trilayer is determined by the low resistance up spin channel which effectively shorts the high-resistance up spin channel. Therefore the total resistance of the trilayer in the ferromagnetic configuration is low.

On the other hand, the following will occur when adjacent layers of ferromagnetic material are magnetized with different polarities (i.e. both layers magnetized with fields in opposite directions). Down spin electrons in the antiferromagnetic configuration are strongly scattered in the first ferromagnetic layer but weakly scattered in the second ferromagnetic layer. The up spin electrons are weakly scattered in the first ferromagnetic layer and strongly scattered in the second. Because of this, there is no effective shorting of a high-resistance channel, and therefore the total resistance in the antiferromagnetic configuration is much higher than in the parallel configuration.

Put another way, when both magnetic fields are parallel to each other in a layer, electrons with up-spin and down-spin will scatter differently through the layers. Current flow through the layers can be thought of as two distinct processes, where up-spin electrons have a set current and set resistance, whilst down-spin electrons have a set current and effective resistance. Therefore resistivity felt by the electrons differs based on the magnetic alignment of the materials and this causes electrons to scatter through the material based on the alignment of the field.

The layers of alternating ferromagnetic and non-magnetic materials may also be referred to as magnetic superlattices. Electric current can be passed through magnetic superlattices in two ways. In a current in plane (CIP) geometry, the current flows along the layers, and the electrodes are located on one side of the structure. In the current perpendicular to plane (CPP) configuration, the current is passed perpendicular to the layers, and the electrodes are located on different sides of the superlattice.

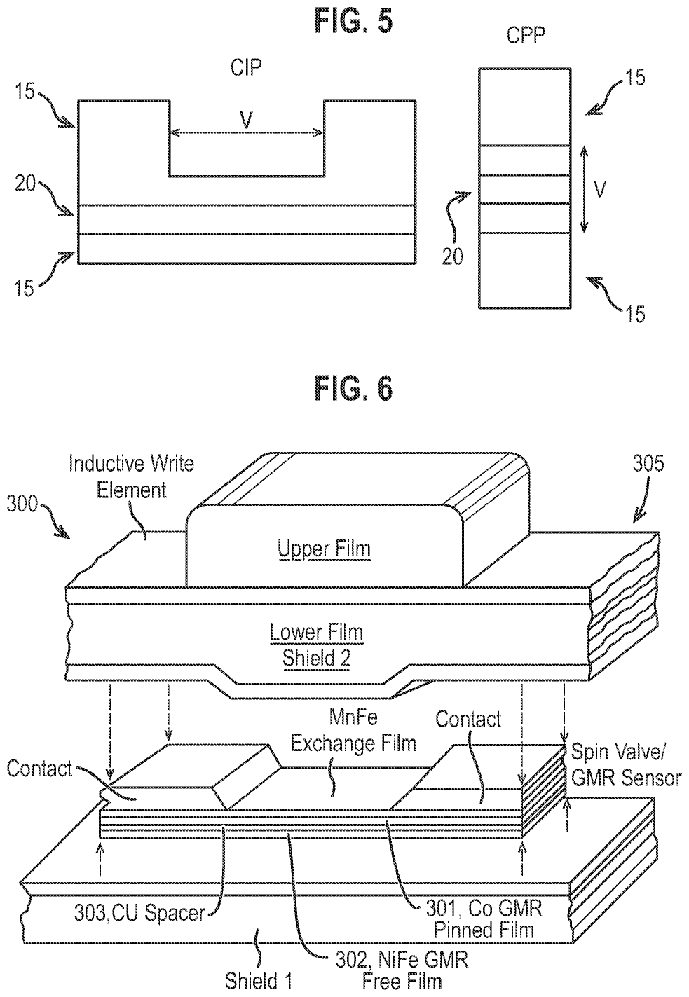

The CPP geometry may be preferable because a higher GMR can be achieved than that of the CIP configuration. Such configurations are depicted in FIG. 5.

The following Valet-Fert model provides an approximation of the GMR effect:

$${R}_{i} = \frac{β ( {μ}_{↑ ↓} - {μ}_{↑ ↑} )}{2 ej} = \frac{{β}^{2} {ℓ}_{sN} {ρ}_{N}}{1 + ( 1 - {β}^{2} ) {ℓ}_{sN} {ρ}_{N} / ( {ℓ}_{sF} {ρ}_{F} )}$$

wherein:
Rᵢ is the interface resistance at the interface between the magnetic and non-magnetic material;
β is the coefficient of the spin anisotropy;
[symbol] ₛ is the average length of spin relaxation;
ρ_{N} is the resistivity of non-magnetic metal;
j is current density in the sample;
[symbol] _{sN} and [symbol] _{sF} are the length of the spin relaxation in a non-magnetic and magnetic materials; and
ρ_{F} is the average resistivity of the ferromagnet.

In some embodiments, the magnetoresistive element comprises a magnetic storage element in a hard disc drive having GMR technology. Such a hard drive includes the requisite hardware for appropriately magnetizing the ferromagnetic layers in parallel and antiparallel arrangements.

FIG. 6 illustrates an exemplary magnetic storage element 300 in a hard disc drive. As can be seen in this figure, two ferromagnetic films are present (a first Co film 301 and a second NiFe film 302, although other ferromagnetic materials can also be used). A non-ferromagnetic material 303 (in this case, Cu) is interposed between the layers of ferromagnetic material.

In some instances, one of the ferromagnetic films has a fixed magnetic orientation, whilst the other film has a free, variable magnetic orientation. Thus, by adjusting the magnetization of the film having the variable magnetic orientation into parallel or antiparallel arrangements with different strengths, the resistance through the two films can be controlled.

The HDD further includes a read/write head 305 (or just a dedicated write head) that comprises an inductive write element (i.e. a control element). The read/write or write head 305 is configured to come into contact with each and every magnetic storage element on the disk platter and control the magnetization of the film having variable magnetic orientation.

A traditional GMR read write head 305 from a hard drive can be used to write weights to the system. As the weights retain their value due to the magnetism of the component, the GMR head does not need to retain long term memory on the strength and location of the weights.

Beyond utilizing the magnetic storage element for its typical purpose (i.e. storing digital data as 1s and 0s), it is an object of the present invention to take advantage of a variable resistance profile, as shown in FIG. 4.

In other words, the write head 305 of the present invention is configured to control the respective polarity of magnetizations between the layers so as to allow for a gradual, sloped control of resistance profile. These magnetic components allow for defining weights of an artificial neural network.

In a typical hard disc drive, there are no designated electrical pathways between each of the magnetic storage elements, as such a device is not designed for computing. In the present invention, the hard disc drive surface is utilized to implement the synapse circuitry, whilst neural architecture exists in one or more separate layers underneath, or on top of, the hard disc drive surface (i.e. the magnetoresistive layer).

In some instances, the one or more separate layers may comprise a silicon layer and an optional interconnectivity layer.

Said silicon layer may comprise logic gates, capacitors, circuit traces, and semiconductor components such as transistors and gates. Said circuitry may be implemented on a printed circuit board with a plurality of vias that make electrical connection to each of the magnetic storage elements on the hard drive.

In instances where there is an interconnectivity layer, the interconnectivity layer is configured to make electrical connection between the magnetoresistive elements of the ferromagnetic hard drive and the silicon layer. These connections can be made via copper brushes, electrical contacts, circuit traces, electrical solder, etc. In one preferred embodiment, the interconnectivity layer comprises copper brushes for contacting respective magnetoresistive elements of the ferromagnetic hard drive.

In cases where the read/write head of the hard disc drive sits on top of the hard disc drive surface, the neural architecture will be arranged on the opposite side (underneath the magnetoresistive layer), and vice versa.

It is therefore understood that the magnetic storage elements of HDD can be configured so that each magnetic storage element acts as a magnetoresistive element. Such elements can be connected with corresponding circuitry on a separate layer of circuitry so as to implement a computing device and/or a neural network architecture.

It may be understood that setting the resistance values of each of these magnetoresistive elements is referred to as a “training” phase, whereby the computing device or artificial neural network is initially configured. When applied into an artificial neural network configuration, each of the magnetoresistive elements can be considered part of an artificial synapse circuit.

The one or more separate layers of circuitry connected to the hard disc drive may comprise connections to source circuitry/read-out circuitry for each magnetic storage element.

The one or more separate layers of circuitry may further comprise connections between respective magnetic storage elements, via artificial neuron circuitry.

For the avoidance of doubt, whilst the present application discusses GMR as an effect that be utilized to control resistance, the application is not intended to be limited as such. Other magnetoresistive effects are also considered, including geometrical magnetoresistance, common positive magnetoresistance, negative magnetoresistance, anisotropic magnetoresistance, tunnel magnetoresistance (TMR), colossal magnetoresistance (CMR), and extraordinary magnetoresistance (EMR). Any of these effects can be implemented either on or off a hard disc drive.

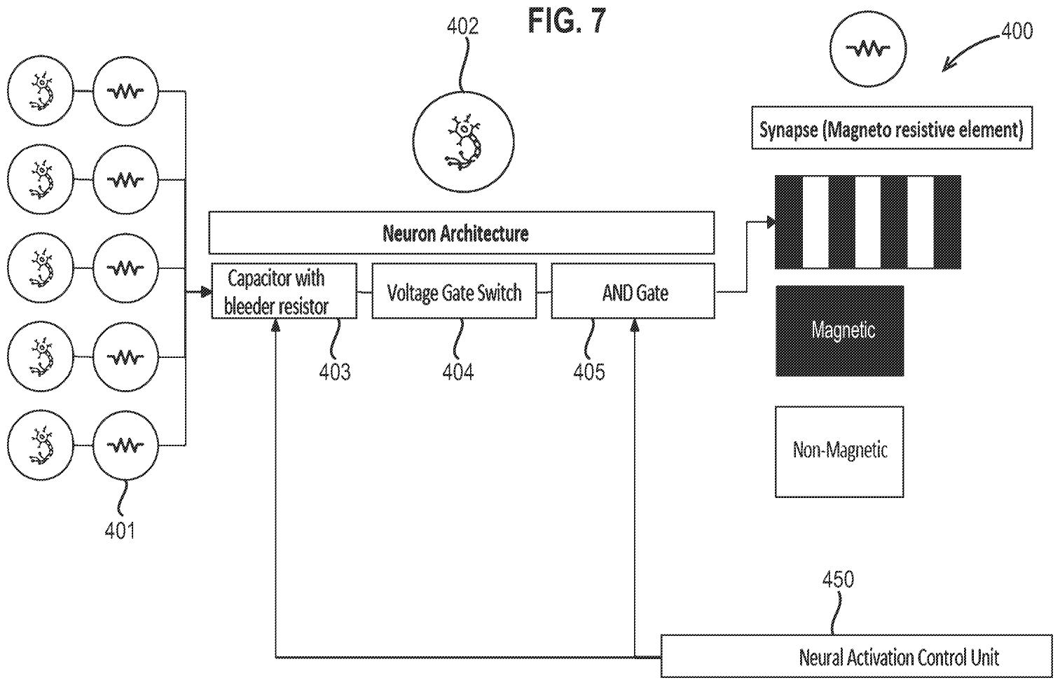

FIG. 7 depicts an exemplary hardware architecture of an artificial neural network with further detail around the neuron architecture which is present on the separate layer of circuitry.

As illustrated in this figure, the artificial neuron circuit 400 is configured to receive signals from a plurality of artificial synapses 401 (in this case, 5 artificial synapses are present, but any number of artificial synapses can be present). These artificial synapses 401 provide a number of weighted inputs to the artificial neuron.

As can be seen from this figure, the neuron architecture 402 (also referred to as the artificial neuron circuitry, or more simply as a neuron) may comprise a capacitor 403 (with an optional bleeder resistor) and an AND gate 405.

In certain arrangements, there may further be a voltage gate 404 switch in the artificial neuron circuit 400, either in addition to the capacitor or as a replacement of the capacitor.

The capacitor 403 and AND gate 405 may each be controlled by a control unit, which may comprise a neural activation control unit 450 for controlling elements of the artificial neuron circuit 402.

The AND Gate 405 can either be positioned within the neuron circuitry 402 or within an artificial synapse 401 depending on neural interconnectivity required. That is, the AND gate 405 can define active neurons or inactive neurons. In other words, the AND gate 405 can perform the function of a disconnect switch (by controlling one of the inputs of the AND gate), to disconnect an electrical pathway either in an artificial synapse circuit or in an artificial neuron circuit.

The AND gate 405 can also be arranged to fire a neuron even when no voltage has charged the neuron itself (by introducing biased voltages). For example, in some cases, a cable delivering a biased voltage can be connected to the output of the AND gate 405 to act as a bypass.

In the illustrated example, the neural activation control can be configured to control one input of the AND gate 405. If this input is pulled low (logical 0), the AND gate 405 will always be OFF, thereby providing a disconnect function.

Whilst FIG. 7 depicts an AND switch 405, the disconnect switch is not limited to such a configuration. Other switching arrangements (other logic gates, such as XOR arrangements, relay switches and transistor switching circuitry such as MOSFETs and BJTs) can also be provided to implement the disconnect functionality.

Whilst not shown here, corresponding disconnect switches can alternatively, or in addition, be provided at the output of each of the artificial synapse circuits so as to implement a similar control mechanism.

The capacitor 403 stores charge when voltage is incident onto it. By providing a capacitor as an artificial neuron, it can be configured to receive a number of input voltages in parallel (based on the number of artificial synapses that feed into the artificial neuron circuit), which allows the capacitor 403 to act effectively as a summing device.

In certain instances, it may be preferable to regulate when the artificial neuron 402 “fires” (i.e. transmits a signal to any number of artificial synapses at its output”).

This functionality can be provided with a voltage gate switch 404. Such a voltage gate switch 404 is configured to regulate any capacitor bleeding and ensure that the corresponding capacitor only fires when a threshold of the voltage gate switch is reached.

Similarly, whilst not depicted in FIG. 7, corresponding voltage gates can alternatively, or additionally, be implemented in the artificial synapse circuits.

In some instances, a bleeder resistor may be provided so as to allow for rapid discharge of the capacitor 403, in the event the capacitor is not fully charged and doesn't fire, providing a temporal form of calculation.

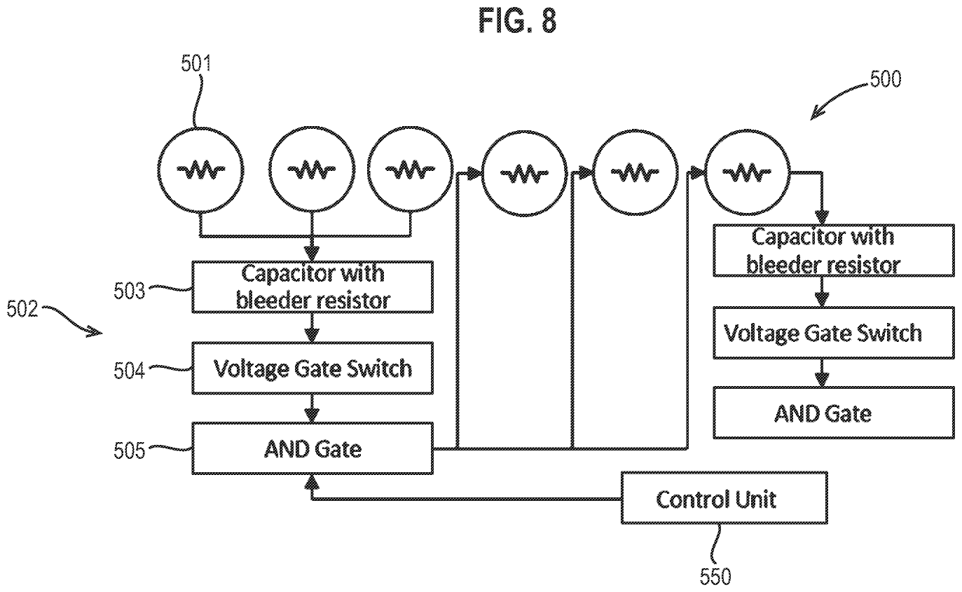

An alternative topology 500 of connections between neurons and synapses is provided in FIG. 8. As can be seen from this arrangement, the artificial neuron circuit 502 (comprising a capacitor 503 with bleeder resistor, voltage gate switch 504, and AND gate 505) is connected to three synapses 501 at its input, and the output of the artificial neuron circuit 502 is connected to three separate synapses.

It is understood that the connections between artificial neurons and artificial synapses are fixed by the separate layer of circuitry which connects electrically to the disk platter of the hard disk drive. In other words, once a device having artificial neurons and artificial synapses is manufactured, the interconnections are fixed. However, as noted above, specific artificial neurons and/or artificial synapses can be disconnected via control of respective disconnect switches present in the artificial neuron circuits or in the artificial synapse circuits so as to enable control of the overall topology of the artificial neural network.

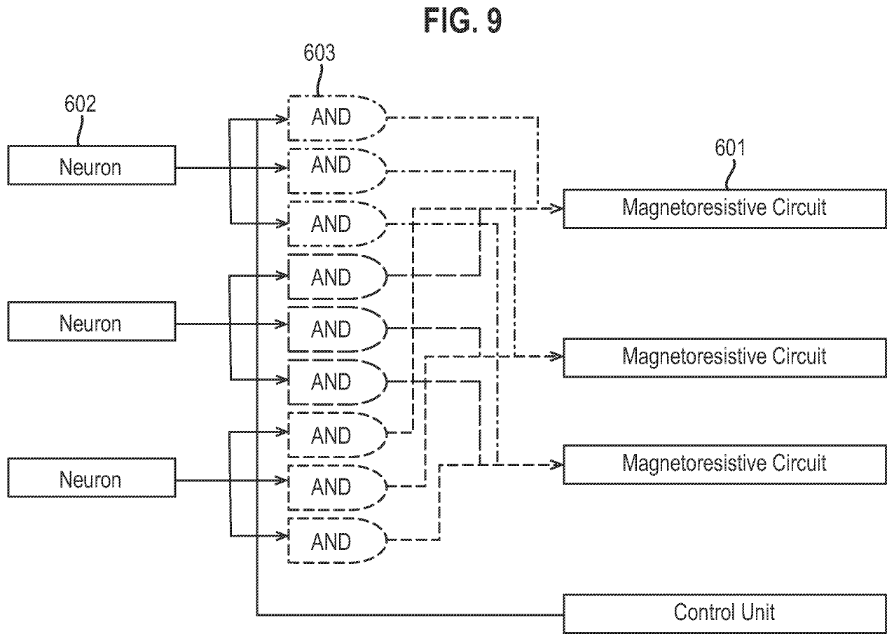

FIG. 9 illustrates an arrangement whereby an artificial synapse circuit 601 can be connected to a plurality of artificial neuron circuits 602 at its inputs via one or more disconnect switches 603.

In this example, each artificial synapse 601 is configured to receive signals from each of the artificial neurons 602 in the preceding layer of the neural network.

Similar to the arrangements discussed previously, a control unit may be present so as to control the disconnect switches 603 (here implemented with AND gates).

In other words, each artificial neuron circuit 602 can be associated with a plurality of disconnect switches 603, and the output of each of the associated disconnect switches is connected to a respective artificial synapse circuit 601. Each artificial synapse circuit 601 can be connected to the output of a plurality of artificial neuron circuits 602, via one of the disconnect switches 603 of each of said plurality of artificial neuron circuits.

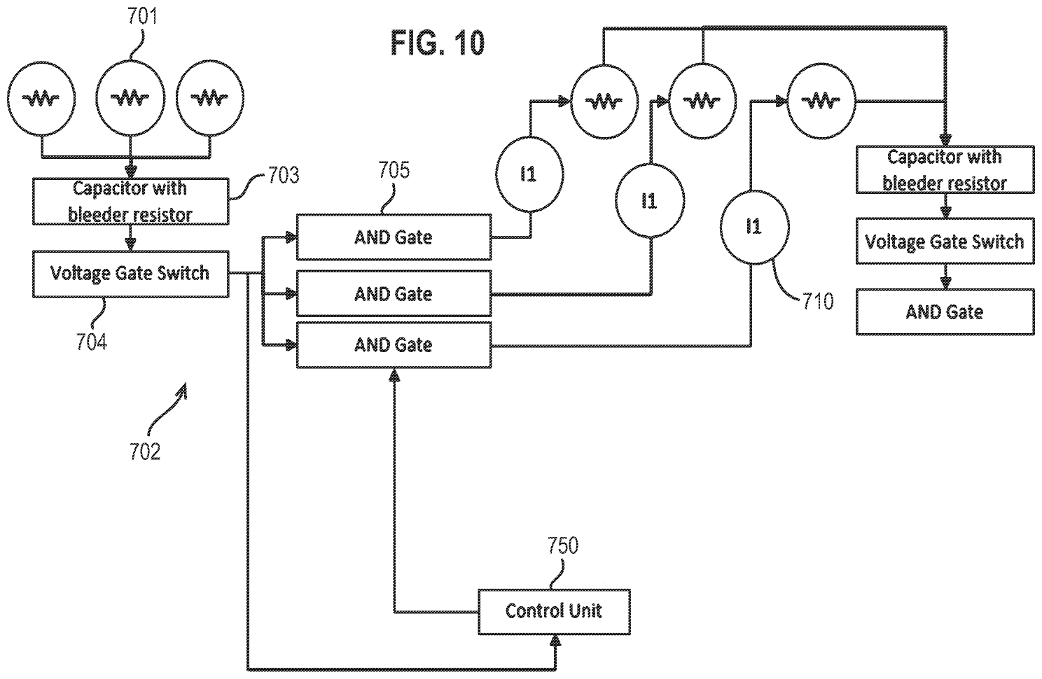

FIG. 10 illustrates an arrangement where it is possible to monitor which artificial neurons 702 have “fired” (i.e. transmitted a signal to any number of artificial synapses at its output”).

The artificial synapses 702 and disconnect switches 705 illustrated in FIG. 10 are similar to those described in preceding embodiments and will not be elaborated on further with respect of FIG. 10.

However, in this illustrated arrangement, the control unit 750 is configured to receive a signal from the output of the voltage gate switch 704. In this way, the control unit is configured to monitor when the voltage gate switch has been triggered, which is indicative that the artificial neuron has fired. This monitoring allows for improved control mechanisms of the artificial neural networks.

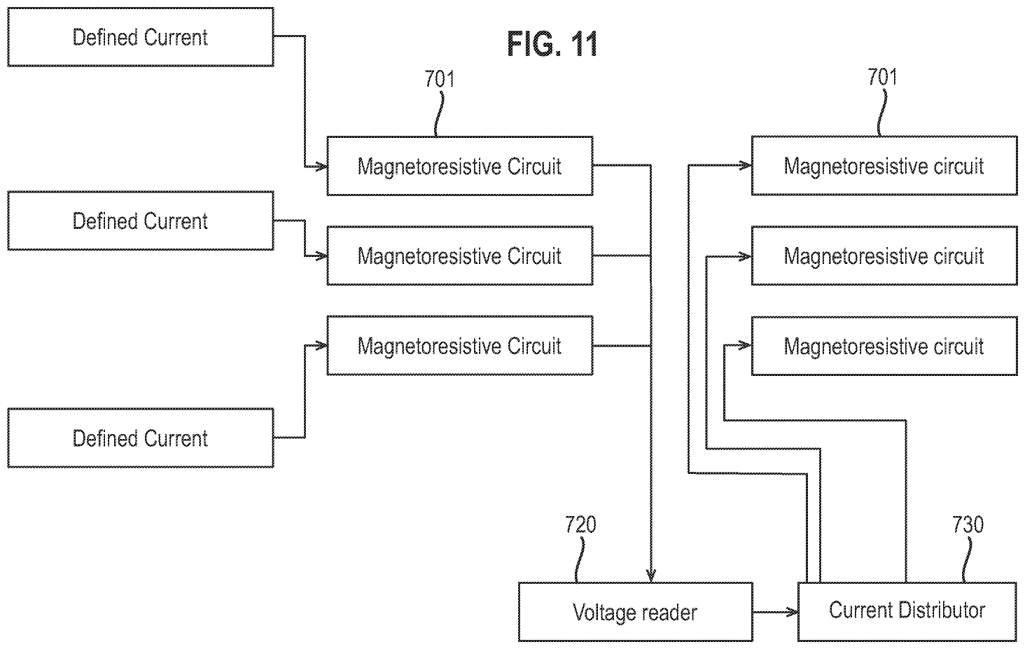

According to alternative embodiments, the artificial neuron circuit 702 can include a voltage reader 720 and current distributor 730, as opposed to a capacitor and a voltage gate. Such an arrangement is illustrated in FIG. 11.

As shown in this figure, each magnetoresistive circuit can be configured to receive a defined current, and a multiplication factor is applied to the respective defined current to produce a respective output voltage.

A voltage reader 720 is configured to receive each of the respective output voltages from the connected magnetoresistive circuits (either independently, or in parallel). In this way, the voltage reader 720 is configured to calculate a sum of all of the defined input currents multiplied by respective resistances from the magnetoresistive circuits (a weighted sum).

As opposed to a voltage gate being implemented to transfer the signal to subsequent artificial synapse circuits, there is provided in this example a current distributor 730. The current distributor 730 is connected to one or more artificial synapse circuits 701 at its output (in the illustrated example, there are 3 connected circuits). The current distributor is configured to generate a new defined current (in accordance with the voltage measured from the voltage reader) to be applied to all of the magnetoresistive circuits connected at its output.

The voltage reader 720 and current reader 730 can each be controlled by a control unit (750) (or more specifically by the neural activation control unit of the control unit). In some examples, the control unit controls the voltage reader and current distributor so that the current distributor outputs at least one current output from the neuron at a certain time interval.

The arrangement of FIG. 11 may be beneficial for the implementation of a traditional (i.e. non spiking) artificial neural network. That is, whereas a spiking neural network relies on transmitting information only when certain parameters are met (thereby mimicking the membrane potential of a biological neuron), such a control is not present in a traditional neural network. Instead, the signals input into a traditional ANN will propagate automatically through each of the layers of the neural network based on clock signals provided by the control unit for the artificial neurons.

In view of the above, it can be understood that different artificial neural network topologies and the connections between synapses and neurons between layers of the ANN can be entirely configurable.

In some instances, each artificial neuron circuit can be configured to receive signals from one or more artificial synapses (which themselves can be connected to individual, respective artificial neuron circuits, or to multiple artificial neuron circuits in parallel).

Each artificial neuron circuit can also be configured to output signals to one or more artificial synapse circuits in parallel. In some instances, the artificial synapse circuits can be configured to receive signals from one or more of the artificial neuron circuits.

By view of this level of control, parallel processing and adjustment of network topologies with the artificial neural network can be achieved.

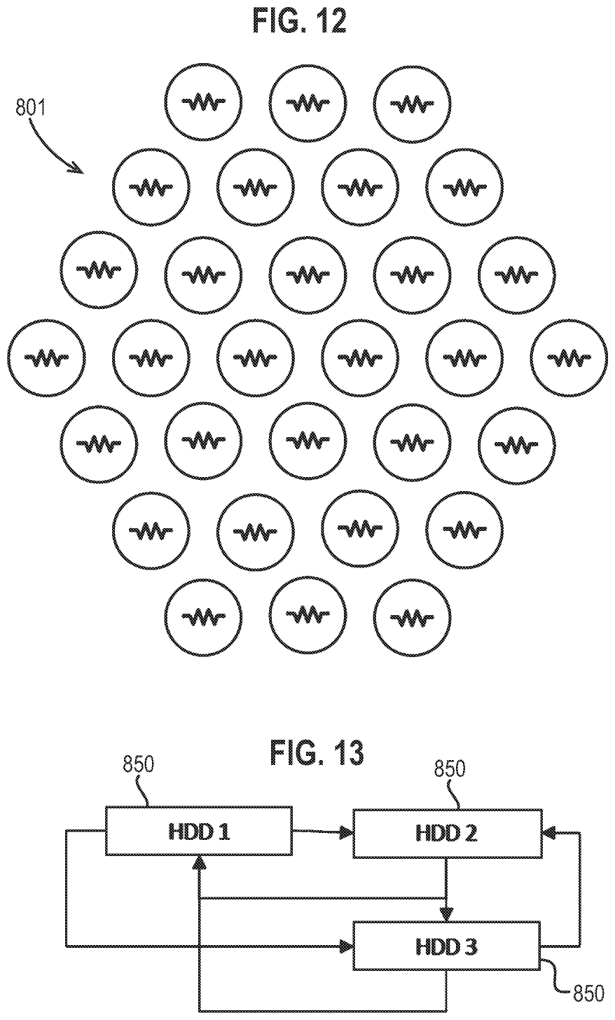

As seen in FIG. 12, the magnetic storage elements which form the magnetoresistive elements 801 may be arranged and dispersed around a disk platter of a hard disc drive. Whilst a discrete number of resistances are provided, the true number of magnetoresistive elements is defined by the number of bits present on a hard disc drive.

As shown in FIG. 13, the application is not limited to a single hard drive 850. That is, because the hard disc drive is utilized so as to provide a set of magnetoresistive elements (which can alternatively be provided without a hard disc drive), a plurality of hard disc drives 850 can also be implemented to increase the number of available hard disc drives 850 (and therefore increase the available number of artificial synapses in an artificial neural network or the number of multiplication elements in a computing device).

When multiple hard drives 850 are utilized, each of these hard drives will be connected to respective neuron circuitry (i.e. the separate layer of circuitry making electrical connection to the magnetoresistive elements). Each of these respective neuron circuits may further be connected to each other by any suitable means (e.g. electrical cabling, circuit traces, etc.).

Providing linked hard disc drives 850 with associated circuitry in this way allows for more complicated neural networks to be achieved and improved parallel processing in a computing device.

For the avoidance of doubt, whilst the present application discusses GMR as an effect that be utilized to control resistance, the application is not intended to be limited as such. Other magnetoresistive effects are also considered, including geometrical magnetoresistance, common positive magnetoresistance, negative magnetoresistance, anisotropic magnetoresistance, tunnel magnetoresistance (TMR), colossal magnetoresistance (CMR), and extraordinary magnetoresistance (EMR). Any of these effects can be implemented either on or off a hard disc drive.

Furthermore, the same principles can also be applied without hard disc drives. That is, by providing a set of magnetoresistive elements that are controllable in the same manner, there is no need to incorporate the specific architecture of a hard disc drive. Nevertheless, implementation of the artificial neural network and computing device on a hard disc drive is advantageous due to the high levels of control and ease in manufacturability of such a device according to the invention.

Unless stated otherwise, terms such as “first” and “second” are used to arbitrarily distinguish between the elements such terms describe. Thus, these terms are not necessarily intended to indicate temporal or other prioritization of such elements. The term “coupled” is defined as “connected” and/or “in communication with,” although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A method for operating an artificial neural network arranged on a computing device, the method comprising:
providing the computing device comprising:
electronic circuitry comprising source circuitry and read-out circuitry;
one or more magnetoresistive elements; and
a control element, configured to magnetize each of the one or more magnetoresistive element to adjust the resistance of each magnetoresistive element between at least three resistance values;
wherein the source circuitry is configured to apply a respective voltage or current to each of the one or more magnetoresistive elements;
wherein the read-out circuitry is configured to output a respective voltage across each of the one or more magnetoresistive elements or a current through each of the one or more magnetoresistive elements, and
in a calculation phase:
applying, via the source circuitry, a respective voltage or current to each of the one or more magnetoresistive elements, and
outputting, via the read-out circuitry, a respective voltage across or a respective current through each of the one or more magnetoresistive elements,
wherein the adjustable resistance of each of the one or more magnetoresistive elements is associated with a respective weight of the artificial neural network.

2. The method of claim 1, further comprising, for each of the one or more magnetoresistive elements:
receiving, from a respective input circuit, the voltage or current to be applied to the respective magnetoresistive element; and
outputting the respective voltage across each of the one or more magnetoresistive elements or the current through each of the one or more magnetoresistive elements to a respective output circuit.

3. The method of claim 2, further comprising:
disconnecting at least one of the respective input circuits from the respective source circuitry;
disconnecting at least one of the one or more magnetoresistive elements from the respective source circuitry;
disconnecting at least one of the one or more magnetoresistive elements from the respective read-out circuitry; or
disconnecting the read-out circuitry from at least one of the respective output circuit.

4. The method of claim 2, wherein the input circuit is a first artificial neuron circuit, and wherein the output circuit is a second artificial neuron circuit.

5. The method of claim 1, further comprising:
in a training phase, setting the resistance of each of the one or more magnetoresistive elements with the control element.

6. The method of claim 1, wherein each of the one or more magnetoresistive elements is a magnetic storage element of a ferromagnetic hard disc drive.

7. The method of claim 6, further comprising:
in a training phase:
setting the resistance of each of the one or more magnetoresistive elements with the control element; and
rotating one or more discs of the ferromagnetic hard disc drive to set the resistance of each of the one or more magnetoresistive elements; and
wherein in the calculation phase, the one or more discs of the ferromagnetic hard disc drive are not rotating.

8. A computing device configured to perform multiplication or division, the computing device comprising:
electronic circuitry comprising source circuitry and read-out circuitry;
one or more magnetoresistive elements; and
a control element, configured to magnetize each of the one or more magnetoresistive elements to adjust the resistance of each magnetoresistive element between at least three resistance values;
wherein the source circuitry is configured to apply a voltage or a current to each of the one or more magnetoresistive elements;
wherein the read-out circuitry is configured to output a respective voltage across each of the one or more magnetoresistive elements or a respective current through each of the one or more magnetoresistive elements.

9. The computing device of claim 8, wherein, for each of the one or more magnetoresistive elements:
the source circuitry is configured to receive the voltage or current to be applied to the respective magnetoresistive element from a respective input circuit; and
the read-out circuitry is configured to output the respective voltage across each of the one or more magnetoresistive elements or the respective current through each of the one or more magnetoresistive elements to a respective output circuit.

10. The computing device of claim 8, where each of the one or more magnetoresistive elements is a magnetic storage element a ferromagnetic hard disc drive.

11. An artificial synapse circuit in an artificial neural network, the artificial synapse circuit comprising:
electronic circuitry comprising source circuitry and read-out circuitry;
an magnetoresistive element; and
a control element, configured to magnetize the magnetoresistive element to adjust resistance of the magnetoresistive element between at least three resistance values,
wherein the source circuitry is configured to apply a voltage or a current to the magnetoresistive element;
wherein the read-out circuitry is configured to output a respective voltage across each of the magnetoresistive element or a respective current through the magnetoresistive element,
wherein the adjustable resistance of each of the one or more magnetoresistive elements is associated with a weight of the artificial synapse in the artificial neural network,
wherein the source circuitry is configured to receive the voltage or current to be applied to the magnetoresistive element from a first artificial neuron circuit, and
wherein the read-out circuitry is configured to output the respective voltage across the magnetoresistive element and/or the respective current through the magnetoresistive element to a second artificial neuron circuit.

12. The artificial synapse circuit of claim 11, further comprising:
a synapse disconnect switch configured to disconnect: the first artificial neuron circuit from the source circuitry, the source circuitry from the magnetoresistive element, the magnetoresistive element from the read-out circuitry, or the read-out circuitry from the second artificial neuron circuit.

13. The artificial synapse circuit of claim 11, wherein the source circuitry is configured to receive the voltage or current from the first artificial neuron circuit and from one or more additional neuron circuits.

14. The artificial synapse circuit of claim 11, wherein the artificial neural network is a spiking neural network, and wherein the artificial synapse circuit further comprises:
a voltage gate configured to allow the current to flow to an output of the artificial synapse circuit if the voltage across the magnetoresistive element exceeds a threshold voltage of the voltage gate, optionally wherein the threshold voltage of the voltage gate is variable, and further optionally wherein the voltage gate comprises a magnetoresistive circuit that allows the threshold voltage to be varied.

15. An artificial neural network circuit, comprising:
a plurality of artificial neuron circuits;
a plurality of artificial synapse circuits, wherein each of the plurality of artificial synapse circuit comprises:
electronic circuitry comprising source circuitry and read-out circuitry;
an magnetoresistive element; and
a control element, configured to magnetize the magnetoresistive element to adjust the resistance of the magnetoresistive element between at least three resistance values,
wherein the source circuitry is configured to apply a voltage or a current to the magnetoresistive element;
wherein the read-out circuitry is configured to output a respective voltage across each of the magnetoresistive element or a respective current through the magnetoresistive element,
wherein the adjustable resistance of each of the one or more magnetoresistive elements is associated with a weight of the artificial synapse in the artificial neural network,
wherein the source circuitry is configured to receive the voltage or current to be applied to the magnetoresistive element from a first artificial neuron circuit, and
wherein the read-out circuitry is configured to output the respective voltage across the magnetoresistive element and/or the respective current through the magnetoresistive element to a second artificial neuron circuit; and
wherein each of the plurality of artificial synapse circuits is connected between a respective two of the plurality of artificial neuron circuits, and
wherein the resistance of the magnetoresistive element in each artificial synapse circuit corresponds to a weight in the artificial neural network.

16. The artificial neural network circuit of claim 15, wherein each artificial neuron circuit further comprises:
a capacitor; and
optionally comprises a voltage gate configured to allow current to flow to an output of the artificial synapse circuit if the voltage across the magnetoresistive element exceeds a threshold voltage of the voltage gate.

17. The artificial neural network circuit of claim 15, wherein at least one of the artificial neuron circuits comprises a neural disconnect switch configured to disconnect said artificial neuron circuit from an artificial synapse circuit at an output or at an input of the artificial neuron circuit.

18. The artificial neural network circuit of claim 15, wherein the artificial neural network is a spiking neural network; and
wherein the artificial synapse circuit further comprises a voltage gate configured to allow current to flow to an output of the artificial synapse circuit if the voltage across the magnetoresistive element exceeds a threshold voltage of the voltage gate; and
wherein the voltage gate of each synapse circuit allows current to flow from one of its respective artificial neuron circuits to the other of its respective artificial neuron circuits.

19. The artificial neural network circuit of claim 15, where each magnetoresistive element is a magnetic storage element, wherein each of the artificial synapse circuits is connected between its respective two artificial neuron circuits by conductive traces, optionally, and wherein each magnetic storage element is a magnetic storage element of a ferromagnetic hard disc drive.

20. The artificial neural network circuit of claim 15, wherein each of the plurality of artificial neuron circuits is configured to:
receive signals from one or more of the artificial synapse circuits;
compute a weighted average of said signals; and
output the sum and/or weighted average.

21. The artificial synapse circuit of claim 11, wherein each magnetoresistive element comprises a layered structure, the layered structure comprising a first magnetic material, a non-magnetic material, and a second magnetic material, optionally wherein the control element is configured to magnetize the first magnetic material and the second material of each magnetoresistive element into a parallel and into an anti-parallel arrangement so as to adjust the resistance.

22. The artificial synapse circuit of claim 11, wherein the magnetoresistive element is a single layer of material.
